(19) United States
(12) Patent Application Publication
(10) Pub. No.: US 2009/0250826 A1
(43) Pub. Date: Oct. 8, 2009

(54) Process for manufacturing semiconductor device and semiconductor device manufactured by such process

(75) Inventor: Teruji Inomata, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/382,538

(22) Filed: Mar. 18, 2009

(30) Foreign Application Priority Data
Apr. 3, 2008 (JP) 2008-096912

(51) Int. Cl. H01L 23/18; H01L 21/50

(52) U.S. Cl. 257/789; 438/124; 438/613; 257/E23.136; 257/E21.499

(57) ABSTRACT

A process for manufacturing a semiconductor device that inhibits deterioration in the quality of the semiconductor device and a semiconductor device manufactured on such manufacturing process are presented. An operation of determining time-variation of water content in the resin substrate 11 (processing S1); an operation of coupling the semiconductor element 12 onto the resin substrate 11 through a plurality of electroconductive bumps B (processing S3); a first heating operation for controlling a water content of the resin substrate 11 to equal to or lower than 0.02% by heating said resin substrate and said semiconductor element while maintaining the coupling through said bumps (processing S6); and a first heating operation for controlling a water content of the resin substrate 11 to equal to or lower than 0.02% by heating said resin substrate and said semiconductor element while maintaining the coupling through said bumps (processing S6); and filling spaces formed by the semiconductor element 12, the resin substrate 11 and the solder bumps B with the resin 15, under the condition that the water content in the resin substrate 11 is equal to or lower than 0.02% (processing S7); are conducted.

This application is based on Japanese patent application No. 2008-096,912, the content of which is incorporated hereinto by reference.

### BACKGROUND

1. Technical Field

The present invention relates to a process for manufacturing a semiconductor device and a semiconductor device manufactured by such process.

2. Related Art

Conventionally, a flip-chip configuration is a suitable packing technology for a semiconductor element with more than a thousands pins. In such configuration, a semiconductor element is coupled to a substrate via a bump. In order to provide a protection for the bump, a resin referred to as an underfill is injected into gaps formed among the substrate, the semiconductor element and the bump, and the injected resin is cured.

In such configuration, the following problems are known when the underfill is utilized. When a large quantity of water is contained in the substrate during the cure of the underfill resin, water vaporizes from the substrate, creating voids in the underfill resin. Such creation of voids leads to a deterioration in the quality of the semiconductor element. In consideration of such situation, Japanese Patent Laid-Open No. 2004-260,096 discloses conducting a first heating step for heating a substrate having an underfill resin at a temperature lower than the boiling point of water after the circuit element is joined to the substrate and the underfill resin is provided, and a second heating step for heating at a temperature higher than the heating temperature in the first heating step. It is also disclosed that the viscosity of the underfill resin can be increased in the first heating step to prevent water from penetrating into the underfill resin. The conventional technology of Japanese Patent Laid-Open No. 2004-260,096 further discloses that water in the substrate is removed by heating the substrate in a heating furnace at 120 degree C. for 5 hours after the circuit element is coupled to the substrate. Further, the related technology for the present invention may include a technology disclosed in Japanese Patent Laid-Open No. 2002-313,841.

In the process described in Japanese Patent Laid-Open No. 2004-260,096, the viscosity of the underfill resin is increased at a temperature under the boiling point of water in the first heating step, and then the underfill resin is cured in the second heating step. When a type of the underfill resin, which is not capable of initiating its cure reaction at a temperature under the boiling point of water, is employed, it is concerned that sufficient increase in the viscosity of the underfill resin cannot be achieved in the first heating step. Therefore, such process cannot firmly prevent a generation of voids. On the other hand, the process described in Japanese Patent Laid-Open No. 2004-260,096 includes heating and drying the substrate and the circuit element, which are then stored in a desiccator, and the substrate may absorb moisture since humidity in the desiccator is not 0% even if it is stored in the desiccator. Therefore, it is difficult to firmly prevent a generation of voids in the underfill.

### SUMMARY

According to one aspect of the present invention, there is provided a process for manufacturing a semiconductor device, the device comprising a resin substrate and a semiconductor element installed on the resin substrate, the process including: electrically coupling the resin substrate with the semiconductor element through a plurality of electroconductive bumps over the resin substrate; controlling a water content of the resin substrate to equal to or lower than 0.02% by heating the resin substrate and the semiconductor element while maintaining the coupling of the substrate with the element through the bumps; and filling a space surrounded by the semiconductor element, the resin substrate and the bump with a resin and curing the resin, wherein the filling the space with the resin and curing the resin includes filling the space with the resin under the condition that the water content of the resin substrate is equal to or lower than 0.02%.

According to such aspect of the present invention, the space surrounded with the semiconductor element, the resin substrate and the bump is filled with the resin under the condition that the water content of the resin substrate is equal to or lower than 0.02%, and the resin is cured. This allows firmly inhibiting a generation of voids in the resin. In addition, the above-described aspect of the present invention prevents the problem of being unable to avoid a generation of voids depending on the type of the resin as described in Japanese Patent Laid-Open No. 2004-260,096, by supplying the resin under the condition that the water content of the resin substrate is equal to or lower than 0.02%. Therefore, deterioration in the quality of the semiconductor device manufactured by the process according to the present invention can be prevented.

In addition, according to another aspect of the present invention, the semiconductor device manufactured by the process as described above is also provided.

According to the present invention, a process for manufacturing a semiconductor device and a semiconductor device manufactured by such process is provided, which firmly inhibits a generation of voids in the resin and prevents deterioration in the quality of the semiconductor device.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a cross-sectional view, illustrating a semiconductor device according to an embodiment of the present invention;

FIG. 2 is a flow chart, showing a process for manufacturing a semiconductor device according to the present invention;

FIG. 3 is a graph, showing a relation of a water content over a storage time of a resin substrate at predetermined temperature and humidity;

FIG. 4 is a partially enlarged graph of FIG. 3;

FIG. 5 is a graph, showing a relation of a content of a resin substrate over a heating time, and a relation of number of generated voids over the heating time;

FIG. 6 is a schematic block diagram of an apparatus employed in the manufacture of the semiconductor device; and

FIG. 7 is a schematic block diagram of an apparatus employed in the manufacture of the semiconductor device.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

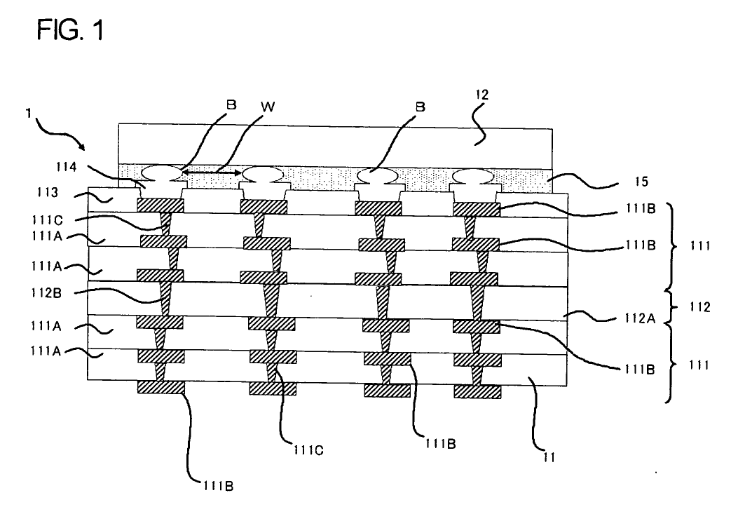

Based on a figure, an embodiment of the present invention is described hereinafter. In the beginning, a structure of a semiconductor device 1 manufactured according to the present embodiment will be described in reference to FIG. 1. The semiconductor device 1 includes a resin substrate 11, and semiconductor elements 12 mounted on the resin substrate 11.

Here, the resin substrate in the present embodiment means a type of a substrate having a resin layer such as an insulating layer, a solder resist film 113 and the like exposed over the surface thereof in the side of the semiconductor element 12, and does not include a type of a multiple-layered member having a surface completely coated by a metallic sheet or the like. In the present embodiment, the resin substrate 11 is so-called build-up substrate, and includes a pair of build-up layers 111 and a core layer 112 disposed between the pair of the build-up layers 111.

The build-up layer 111 is composed of insulating layers 111A containing a resin and conductor interconnect layers 111B, which are alternately placed, and for example, includes a plurality of insulating layers 111A and a plurality of conductor interconnect layers 111B. It is preferable to include 1 to 5 insulating layers 111A that constitute the respective build-up layers 111, and it is also preferable to include 1 to 5 conductor interconnect layers 111B. The resin for constituting the insulating layer 111A may include, for example, epoxy resins and the like. Electric conductors 111C coupled to the conductor interconnect layers 111B are disposed in the insulating layers 111A. The core layer 112 is configured that an electric conductor 112B (for example, metal of copper) extends through an insulating layer 112A, and an electric conductor 112B is coupled to a conductor interconnect layer 111B of the build-up layer 111.

The insulating layer 112A of the core layer 112 and the insulating layer 111A of the build-up layer 111 are composed of a resin such as, for example, an epoxy resin, as a major constituent. Further, the insulating layer 112A of the core layer 112 may include a fiber base member. In addition, a solder resist film 113 (insulating film) having openings formed therein is provided in the surface of the build-up layer 111. The solder sections 114 coupled to the conductor interconnect layer 111B are exposed from the respective opening of this insulating film 113. Typical solder resist film 113 includes, for example, a film formed by employing epoxy-containing resins. Here, the solder section 114 is composed of lead-free solder such as Sn/Bi, Sn/Ag. The solder sections 114 are formed according to the arrangement of the solder bumps B as discussed later.

The semiconductor element 12 is coupled to the resin substrate 11 in a flip-chip configuration. More specifically, a plurality of solder bumps B are coupled to the surface of the semiconductor element 12, and such solder bumps B are coupled to the solder sections 114 of the resin substrate 11 to provide electrical coupling between the semiconductor element 12 and the resin substrate 11. The solder bump B is composed of lead-free solder such as tin/bismuth (Sn/Bi), tin/silver (Sn/Ag) and the like. The distance (W shown in FIG. 1) between the adjacent solder bumps B is equal to or smaller than 200 μm. In addition, the distance between the solder bumps B are equal to or larger than 75 μm.

Spaces created among the above-described semiconductor element 12, the solder bumps B and the resin substrate 11 are filled with a resin (underfill resin) 15. Such resin 15 is charged so as to be in contact with the semiconductor element 12, the solder bumps B and the resin substrate 11. Typical material of the resin 15 includes, for example, resin containing a thermosetting epoxy resin with an inorganic filler as a main component.

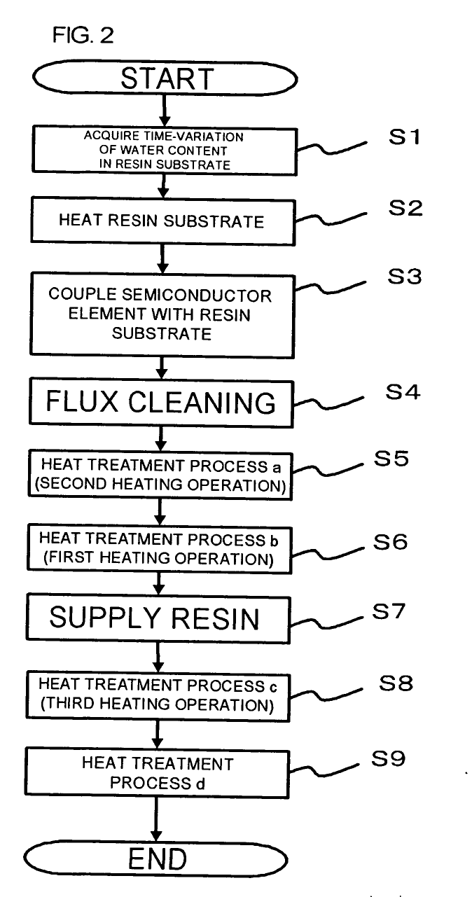

The semiconductor device 1 as described above is manufactured according to the following process. In the beginning, an overview of the process for manufacturing the semiconductor device 1 in the present embodiment will be described in reference to FIG. 2. The present embodiment involves:

an operation of previously determining time-variation of water content in the resin substrate 11 (processing S1);

an operation of coupling the semiconductor element 12 onto the resin substrate 11 through a plurality of electroconductive bumps B (processing S3);

a first heating operation for controlling a water content of the resin substrate 11 to equal to or lower than 0.02% by heating the resin substrate and the semiconductor element while maintaining the coupling through the bumps (processing S6); and

a second heating operation for degassing the resin substrate 11 and the semiconductor element 12 by heating the resin substrate 11 and the semiconductor element 12 to remove a gas derived from a constituent of the resin substrate 11, which are carried out after the operation of coupling the resin substrate with the semiconductor element 12 through the plurality of electroconductive bumps B on the resin substrate 11 and before the first heating operation for controlling the water content of the resin substrate 11 to equal to or lower than 0.02% (processing S5).

Thereafter, an operation of filling a gap surrounded by the semiconductor element 12, the resin substrate 11 and the bumps B with a resin under the condition that the water content of the resin substrate is equal to or lower than 0.02% and curing the resin is conducted (processing S7,S8).

The time elapsed from the end of the second heating operation for degassing the resin substrate 11 to the start of the first heating operation for controlling the water content of the resin substrate 11 to equal to or lower than 0.02% is determined, and the water content of the resin substrate 11 immediately before the first heating operation for controlling a water content of the resin substrate 11 to equal to or lower than 0.02% is determined. Then, the heating time for the first heating operation of controlling the water content in the resin substrate 11 to equal to or lower than 0.02% is established on the basis of the determined water content, and the water content in the resin substrate 11 is controlled as being equal to or lower than 0.02%.

Next, the process for manufacturing the semiconductor device 1 of the present embodiment will be described in detail. In the beginning, the time-variation of the water content in the resin substrate 11 is determined under a predetermined environment (predetermined humidity and temperature) (processing S1). Here, “under a predetermined environment (predetermined humidity and temperature) means a humidity and a temperature in a place where the resin substrate 11 is stored from the completion of the second heating operation to the beginning of the first heating operation.

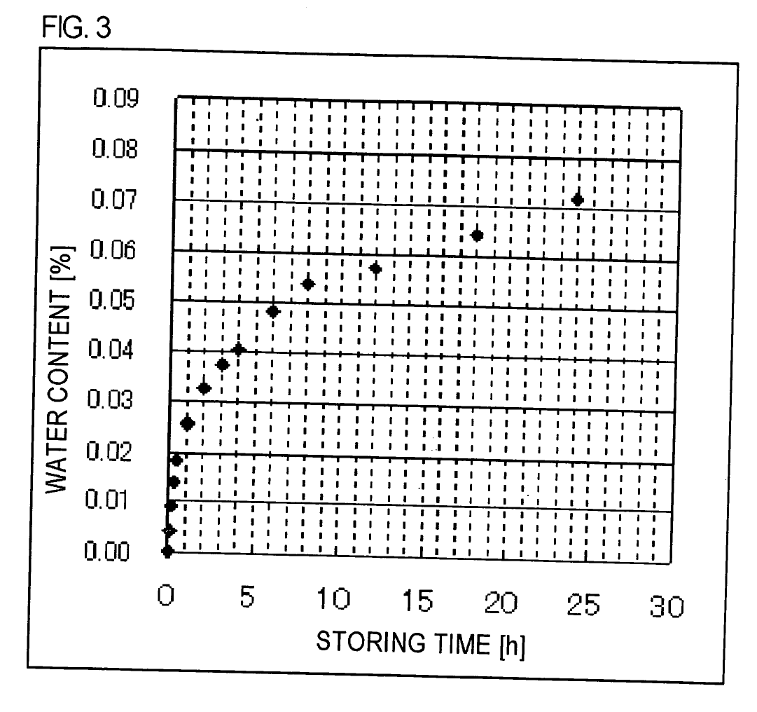

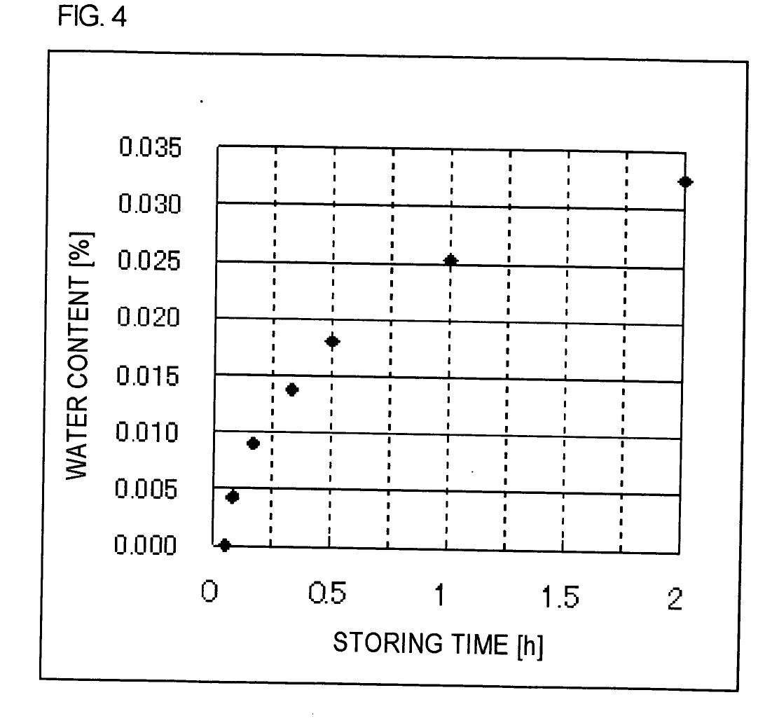

For example, the time-variation of the water content of the resin substrate 11 at a humidity of 50% and a temperature of 22.5 degree C. is as shown in FIG. 3 and FIG. 4. FIG. 4 shows a part of the variation shown in FIG. 3.

Next, the resin substrate 11 is heat-treated (processing S2). No semiconductor element 12 is installed over the resin substrate 11, and thus the resin substrate 11 itself is heat-treated. The heat treatment process in such processing S2 is aimed for vaporizing water contained in the resin substrate 11 to prevent a breakdown of the substrate by water vapor during a reflow soldering processing. The heating temperature T0 in the processing S2 is selected to be lower than the lowest one of the decomposition temperature of the resin substrate 11 and the melting point of the solder section 114.

Thereafter, the semiconductor element 12 is installed through the solder bumps B over the resin substrate 11. The resin substrate 11 that the semiconductor element 12 is installed thereon is disposed in a reflow furnace, and then a reflow soldering process is conducted to provide a coupling of the solder section 114 of the resin substrate 11 with the solder bumps B. This allows providing an electrical coupling between the resin substrate 11 and the semiconductor element 12 (processing S3). In the case of employing the flux for coupling the solder bumps B with the solder section 114, if a cleaning for the flux is required, a flux cleaning for the semiconductor device 1 is conducted. The flux cleaning is conducted by using an organic solvent (processing S4).

Next, the semiconductor device 1 is heat-treated with a heating apparatus (heating furnace) (second heating operation, heat treatment process a, processing S5). The heat treatment process in this stage is aimed for generating gases (outgases) of the constituents of the resin substrate 11 from the resin substrate 11, and for preventing a generation of a gas of the constituents of the resin substrate 11 in the later operations. When the flux cleaning is conducted, a removal of water, which is employed for removing the cleaning solution constituents and the cleaning solution adhered onto the resin substrate 11 during the flux cleaning operation, is simultaneously conducted. The reason is for preventing a release of gases of the constituents absorbed in the resin substrate 11 from the resin substrate 11 in the later operations by conducting the heat treatment process (heat treatment process a, processing S5). The heating temperature T1 in such processing S5 is selected to be lower than the lowest one of the decomposition temperature of the resin substrate 11, the melting point of the solder section 114 and the melting point of the solder bump B. In such heat treatment process operation, a plurality of semiconductor devices 1 may be simultaneously heat-treated.

The semiconductor device 1, which has been processed by the above-described operations, is stored in a clean room at predetermined humidity and temperature (humidity and temperature in the processing S1) for a predetermined time. Here, the reason for requiring the operation for storing the semiconductor device 1 is as follows. While a number of semiconductor devices 1 may be simultaneously processed in the heating operation S5, only a smaller number (for example, one) of the semiconductor device(s) 1 can be processed in one processing cycle in the later operation for injecting the resin. Therefore, the injection of the resin 15 cannot be conducted in one process for all the processed semiconductor devices 1 right after the completion of the heating operation S5, and thus the operation of storing the devices is required.

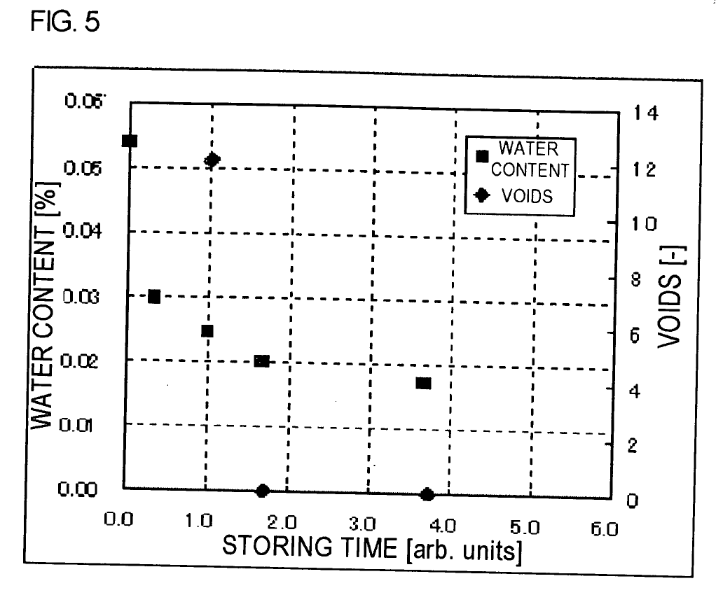

Next, a heat treatment process for the semiconductor device 1 is conducted with a heating apparatus (first heating operation, heat treatment process b, processing S6). Typical heating apparatus includes an apparatus having a heating unit such as a hot plate and the like, and a type of the heating apparatus having a heating unit that is opened to an atmospheric air may be employed, or another type of the heating apparatus having a heating unit that is closed by being surrounded by a wall or the like may also be employed. The heat treatment process here is aimed for removing water absorbed in the resin substrate 11 from the completion of the processing S5 to the commence of the processing S6. The time elapsed from the end of the processing S5 to the beginning of the processing S6 is determined. Next, water content of the resin substrate 11 is acquired on the basis of the time-variation of water content of the resin substrate 11 determined in the processing S1. In such case, an assumption that the water content of the resin substrate 11 right after the end of the processing S5 is 0% is adopted. Next, the heating time in the processing S6 is defined so as to have the acquired water content of the resin substrate 11 of equal to or lower than 0.02% by the heat treatment process. In addition to above, in order to define the heating condition, the relation of the heating time at the heating temperature of the processing S6 and the water content in the resin substrate 11 is previously determined, and the heating time is defined from the aforementioned relationship and the water content of the resin substrate 11 acquired on the basis of the time-variation of the water content in the resin substrate 11 (see FIG. 5).

Here, the significance of controlling the water content to be equal to or lower than 0.02% will be described. FIG. 5 shows a relation between the water content of the resin substrate 11 and the heating time at a predetermined temperature (95 degree C.) (left ordinate and abscissa in FIG. 5) and a relation between the heating time at a predetermined temperature (95 degree C.) and frequency of voids generated in the resin 15 (right ordinate and abscissa in FIG. 5.) In this graph, the voids having apertures of 75 μm or larger are counted as the voids. It is considered by referencing FIG. 5 that no void is generated in the resin 15 if the water content is equal to or lower than 0.02%. Therefore, the heating should be controlled so as to provide the water content of the resin substrate 11 of equal to or lower than 0.02%. In addition to above, the phenomenon of preventing a generation of voids in the resin 15 by controlling the water content in the resin substrate 11 of equal to or lower than 0.02% may be equally adopted for general resin substrates, regardless of number of layers such as insulating layers, conductor interconnect layers and the like or a presence of a core layer, which are typically included in the build-up resin substrate 111 having such layers with general number of layers, such as 1 to 5 insulating layers constituting the respective build-up layers and 1 to 5 conductor interconnect layers. The reason for such phenomenon is considered that water contained in the lower insulating layers in the resin substrate may cause a generation of voids, in addition to water contained in the insulating layers in the side of the surface of the resin substrate. In addition, since the heat treatment process eliminates a basis for generating voids resulted from water, the phenomenon of preventing a generation of voids in the resin 15 by controlling the water content in the resin substrate 11 of equal to or lower than 0.02% is independent with the type of the material of the resin 15. In addition, the heating temperature T2 in the processing S6 is equal to or higher than 95 degree C., and is preferable to be a temperature that is lower than T1. T2 is selected to be lower that T1 so that a generation of outgas from the resin substrate 11 is prevented.

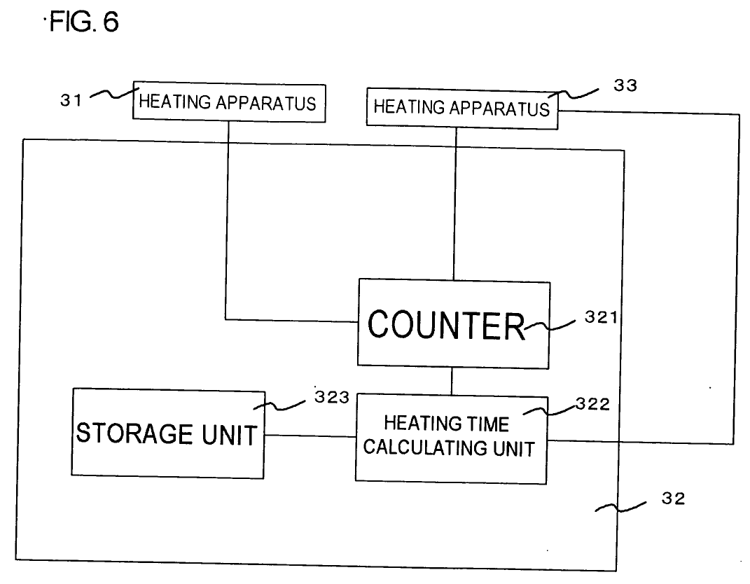

Here, the production control in the processing S5 and S6 may be carried out by employing a control unit 32 shown in FIG. 6. The control unit 32 is coupled to a heating apparatus 31 for conducting the processing S5 and a heating apparatus 33 for conducting the processing S6, and includes a counter 321, a heating time calculating unit 322 and a storage unit 323. The counter 321 is coupled to the heating apparatus 31 and the heating apparatus 33, and detects the end of the heat treatment process in the heating apparatus 31 and the start of the heat treatment process in the heating apparatus 33, and record a time elapsed from the end of the heat treatment process in the heating apparatus 31 to the start of the heat treatment process in the heating apparatus 33. For example, when the heating in the heating apparatus 31 is finished, a signal indicating the end of the heating is sent to the control unit 32 with lot number identifying the semiconductor device. Next, once an operator enters the lot number for the semiconductor device to the heating apparatus 33 and the heating in the heating apparatus 33 is started, the lot number for identifying the semiconductor device and a signal indicating the start of the heating are sent to the control unit 32. The heating time calculating unit 322 acquires the time counted by the counter 321 to calculate the heating time. The time-variation of the water content stored in the storage unit 323 (acquired by the processing S1, see FIGS. 3 and 4) is read out, and the water content associated with the time counted by the counter 321 is acquired. Next, the relation between the heating time and the water content at the heating temperature in the heating apparatus 33 is read out from the storage unit 323 (indicated by left ordinate and abscissa in FIG. 5), and the heating time for achieving the water content to be equal to or lower than 0.02% is read out from the acquired water content.

This allows calculating the heating time in the heating apparatus 33.

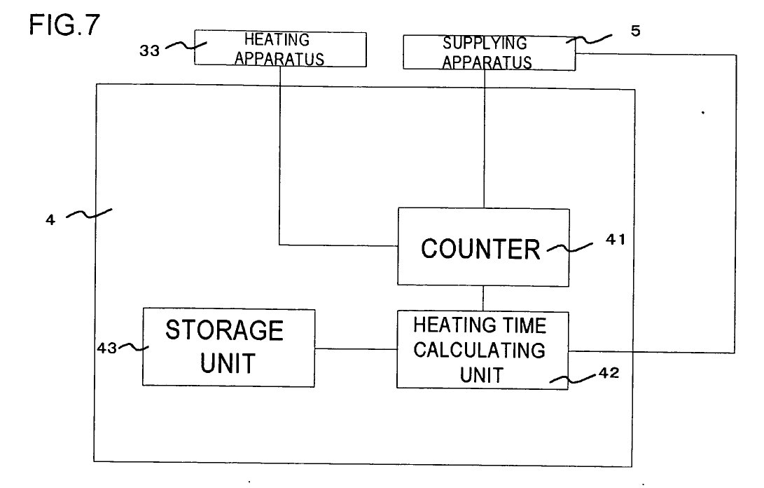

Next, spaces formed by the resin substrate 11, the semiconductor element 12 and the solder bumps B are filled with the resin 15, under the condition that the water content in the resin substrate 11 is equal to or lower than 0.02% (processing S7). A supplying apparatus such as a dispenser and the like is employed for supplying the resin 15. Here, in order to supplying the resin 15 under the condition that the water content in the resin substrate 11 is equal to or lower than 0.02%, it is preferable to carry out the operation for supplying the resin 15 successively with the processing S6. In addition to above, when the process as a sufficient time for achieving the water content of 0.02% starting from the water content of the resin substrate 11 just after the processing S6, the processing S7 needs not to be sequentially conducted with the processing S6. For example, the water content of the resin substrate 11 is controlled to be 0.00% in the processing S6. As shown in FIG. 4, the time duration of about 30 minutes is required for achieving the water content of the resin substrate 11 to be 0.02%. Thus, it is preferable to take the time from the end of the processing S6 to the start of the processing S7 as within 30 minutes. In addition, in the present operation, the control of the water content in the resin substrate 11 may be conducted by employing the control unit 4 as shown in FIG. 7. For example, a control unit 4 having a counter 41, a controller unit 42 and a storage unit 43 is employed. The counter 41 set the time just after the end of the heat treatment process in the heating apparatus 33 as zero (for example, the point in time for opening the door of the heating apparatus 33), and counts the time duration required for the start of the supply of the resin (for example, the time until the semiconductor device is installed). Next, the time-variation of the water content in the resin substrate 11 stored in the storage unit 43 is read out by the controller unit 42 (for example, see FIGS. 3 and 4, the time-variation in the environment where the resin substrate 11 is placed from the end of the processing S6 to the start of the supply of the resin), and the water content of the resin substrate 11 is detected from the time duration counted by the counter 41.

Then, the controller unit 42 determines whether the water content of the resin substrate 11 is equal to or lower than 0.02% or not, and if the water content of the resin substrate 11 is larger than 0.02%, then a command for not supplying the resin 15 is sent to the supplying apparatus 5 for supplying the resin 15 (dispenser) to stop the supply of the resin 15, and it the water content is equal to or lower than 0.02%, then the supplying apparatus 5 is instructed to supply the resin 15 to conduct the supply of the resin 15. In addition to above, the time-variation of the water content of the resin substrate 11 in the location (atmosphere) where the semiconductor device 1 is stored after the end of the processing S6 to the start of the supply of the resin may be previously acquired, and then may be stored in the storage unit 43.

Thereafter (immediately after filling the resin, without leaving semiconductor device 1), the semiconductor device 1 is heat-treated in the heating apparatus (heating furnace) to cure the resin 15. This heating process is conducted under the condition that the water content of the resin substrate is equal to or lower than 0.02%. The heating temperature T3 in this operation may be preferably lower than T1. T3 is selected to be lower that T1 so that a generation of outgas from the resin substrate 11 is prevented (third heating operation, heat treatment process c, processing S8).

Next, the semiconductor device 1 is heated again in the heating apparatus (heating furnace) (heat treatment process d, processing S9). The heat treatment process (heating temperature T4) in this operation is conducted if the heat treatment process for achieving higher temperature higher than T1 is required for obtaining desired characteristics of the underfill resin. The semiconductor device 1 is completed by the above-described operations.

Next, advantageous effects of the present embodiment will be described. In the present embodiment, the resin 15 is supplied to the spaces or the gaps surrounded by the semiconductor element 12, the resin substrate 11 and the bumps B under the condition that the water content of the resin substrate 11 is equal to or lower than 0.02% and the resin 15 is cured. This ensures inhibiting a generation of voids in the resin 15. This allows preventing a quality deterioration of the manufactured semiconductor device 1. In particular, in the present embodiment, the distance between the solder bumps B is provides as equal to or smaller than 200 μm. When the solder bumps B are arranged with such narrower inter-bump distances, a void in the resin 15 may cause unwanted coupling between the solder bumps B. A generation of such voids may cause the melted solder bump B and the melted solder section 114 entering into the voids, leading to creating an electrical coupling between the solder bumps B fellow, thereby possibly cause a short-circuit. Since the solder bumps B and the solder sections 114 are composed of lead-free solder in the present embodiment, the solder bumps B and/or the solder sections 114 may be melted when the semiconductor device 1 is installed onto a mother board to cause a penetration of such melted material in the voids. On the contrary, since the generation of voids in the resin 15 can be inhibited according to the process in the present embodiment, deterioration in the quality of the semiconductor device 1 can be prevented.

In the conventional semiconductor device, lead-containing solder is often employed for the bumps for coupling the semiconductor element with the resin substrate. Therefore, even if the semiconductor device is heated in the process for installing the semiconductor device onto the mother board, the bumps are not melted, and thus short circuits resulted from the coupling of the bumps are scarcely caused. In addition, the distance between the bumps that couple the semiconductor element with the resin substrate is relatively larger in the conventional semiconductor device (for example, about 250 μm). Therefore, even if smaller voids are generated in the underfill, the voids do not connect the bumps. Therefore, even if the bumps are melted, it scarcely happens that the bumps are connected to cause a short-circuit. On the contrary, in the semiconductor device 1 of the present embodiment, the distances between the solder bumps B are selected to be equal to or lower than 200 μm and lead-free solder is employed for the bumps B and the solder section 114, as described above. Therefore, the heating time and the storage time should be strictly managed to avoid a generation of even relatively smaller voids. Thus, in the present embodiment, the time-variation of the water content in the resin substrate 11 is previously determined, and the time elapsed from the end of the heating operation for outgassing from the resin substrate 11 (processing S5) to the start of the heating operation for providing the water content of the resin substrate 11 of equal to or lower than 0.02% (processing S6) is determined. Then, the water content of the resin substrate 11 right before the heating operation for providing the water content of the resin substrate 11 of equal to or lower than 0.02% is determined on the basis of the determined time and the data of the time-variation of the water content in the resin substrate 11, and the heating process is carried out on the basis of the determined water content to achieve the controlled water content of the resin substrate 11 as equal to or lower than 0.02%. This ensures the water content of the resin substrate 11 to be equal to or lower than 0.02%, so that the prevention for generation the voids in the resin 15 is strictly managed.

On the other hands, Japanese Patent Laid-Open No. 2002-313,841 describes that a sealant is supplied after the substrate is dried, and then the semiconductor chip is compressively adhered thereto and the sealant is cured. It is also disclosed that the supply of the sealant should be carried out over a short period of time in such process, in order to hold the temperature of the substrate at a drying temperature from the compressive bonding process of the semiconductor chip and the curing process of the sealant. In such type of process, a series of operations from drying the substrate to supplying the sealant should be rapidly carried out, and thus, if a plurality of substrates are to be dried, it is difficult to carry out the supply of the sealant while holding all the substrates at the drying temperature. In addition, while Japanese Patent Laid-Open No. 2002-313,841 also describes that the substrate is heated again to carry out the compressive bonding of the the semiconductor chip and the cure of the sealant if the temperature of the substrate is decreased due to the standing still after drying the substrate, such increase of the temperature of the substrate to the drying temperature does not necessarily achieve the sufficient removal of water in the substrate. Therefore, a generation of voids due to water in the substrate in may be caused in the sealant. On the contrary, it is found in the present embodiment that voids are easily generated in the resin 15 when the water content in the resin substrate 11 is beyond 0.02%, and the time-variation of the water content in the resin substrate 11 is determined. Therefore, even if a number of semiconductor devices are treated in the heat processing operation S5 and the processed semiconductor devices are stored in a predetermined location, the water content in the resin substrate 11 can be calculated based on the storage time and the time-variation of the water content of the resin substrate 11. Then, a heat-processing is conducted in the heat processing operation S6 according to the calculated water content to control the water content of the resin substrate 11 to be equal to or lower than 0.02%, and then the resin is supplied while maintaining such condition to ensure preventing a generation of voids.

Further, many of the underfill resins that are currently employed are cured at a temperature of equal to or higher than 100 degree C. Therefore, in the process described in Japanese Patent Laid-Open No. 2004-260,096, it is difficult to obtain sufficiently increased viscosity of the underfill resin in the first heating operation of Japanese Patent Laid-Open No. 2004-260,096. Therefore, it is difficult to firmly prevent a generation of voids. In addition, a need for employing a special resin, which provides an increased viscosity of the underfill resin under the condition employed in the first heating operation disclosed in Japanese Patent Laid-Open No. 2004-260,096, is caused, leading to a problem of being unable to employ a general purpose underfill resin. On the contrary, since the resin 15 is supplied under the condition for providing the water content of the resin substrate 11 to be equal to or lower than 0.02% in the present embodiment, a generation of void can be firmly inhibited, and a need for employing a resin having a special composition for the resin 15 is eliminated.

Further, in general, in order to carry out the seal with the resin within a short period of time, it is necessary to provide a reduced viscosity of the underfill resin when the spaces between the bumps are filled with the underfill resin. It is general to utilize a heating process as a manner for providing a reduced viscosity of the underfill resin. A use of a type of resin, which exhibits an increased viscosity when the resin is heated to a temperature below the boiling point lower of water, is required in the process described in Japanese Patent Laid-Open No. 2004-260,096. When such underfill resin is injected to the spaces between the bumps, the reduction of the viscosity of the resin should be achieved by heating the resin to a temperature, which is lower than the above-described temperature for obtaining the increase of the viscosity. In this case, it is presumed that an appropriate viscosity of the resin cannot be obtained for suitably supplying the underfill resin via a capillary phenomenon. Further, even if the supply of the underfill resin can be conducted, it is also presumed that longer period of time is required until the completion of the resin seal. On the contrary, a use of a special resin, which exhibits an increased viscosity at a temperature below the boiling point of water, is not required in the present embodiment, and a general underfill resin may be employed, so that a rapid supply of the underfill resin can be achieved.

The present invention is not limited to the above-mentioned embodiments, and a modification or an improvement within the range for achieving the purpose of the present invention are also included in the present invention. For example, while the build-up substrate having the core layer 112 and the build-up layer 111 is employed for the resin substrate 11 in the above-described embodiments, the resin substrate 11 is not limited thereto, and a build-up substrate having no core layer may also be employed.

Further, while the resin substrate 11 has the solder resist film 113 in the above-described embodiment, the resin substrate 11 is not limited thereto, and the resin substrate 11 may not include the solder resist film 113. In addition, the semiconductor device 1 is heated in the processing S9 in the above-described embodiment, the process is not limited thereto, and the heating operation of the processing S9 may not be conducted.

### EXAMPLES

Next, examples of the present invention will be described.

In the beginning, the time-variation of the water content in the resin substrate was measured. In the present examples, build-up substrates including a core layer having a glass cloth, which contains an epoxy resin impregnated therein, and a pair of build-up layers disposed over and under the core layer were employed for the resin substrate. The respective build-up layers include two insulating layers containing an epoxy resin and a conductor interconnect layer. In addition, a solder resist is formed in the surface of the resin substrate. The resin substrate is disposed in a bake furnace and heated at 125 degree C. for 8 hours. Such heating at 125 degree C. for 8 hours achieved the water content in the resin substrate of 0%. The weight of the resin substrate was measured with an electronic chemical balance within 3 minutes from the point in time when the bake chamber is opened. In this case, the weight of the resin substrate (initial weight of resin substrate) was 20.45643 g. Next, the resin substrate, the weight of which was measured, was left in a clean room at a temperature of 22.5 degree C. and a humidity of 50%, and the weight of the resin substrate after a predetermined time was measured with the electronic chemical balance. For example, the weight of the resin substrate after 5 minutes was 20.45730 g. The water content was obtained according to the following equation:

[(weight of resin substrate at each elapsed time−initial weight of resin substrate)/initial weight of resin substrate]×100(%)

The above-described operations were carried out to obtain a total weight of 10 resin substrates for the purpose reducing an error in the measuring apparatus. The relation of water content over the elapsed time was calculated from such results to prepare FIGS. 3 and 4.

Next, a semiconductor element is installed on a resin substrate, which was the same type as employed in preparing FIGS. 3 and 4, and the processing S2 to processing S5 were conducted. The water content of the substrate just after the processing S5 was 0%. Then, the substrate was left in the clean room at a temperature of 22.5 degree C. and a humidity of 50% for 480 minutes to control the water content of the resin substrate to be 0.055%. Next, such semiconductor device is heated at 95 degree C. (periphery of heating unit (hot plate) was opened to atmospheric air)and the elapsed time was also recorded, and the weight of the semiconductor device was measured with the electronic chemical balance at each of the predetermined elapsed time. Then, the water content of the resin substrate was calculated:

[(weight of semiconductor device at water content of 0.055%−weight of semiconductor device in each elapsed time)/weight of semiconductor device at water content of 0%]×100(%)

The relation of the water content over the heating time shown by the left ordinate and the abscissa in FIG. 5 was prepared by the above described results.

The resin substrates employed in the following examples and the comparative examples were the same type of the resin substrate as employed for preparing FIGS. 3 to 5.

### Example 1

Next, a semiconductor element was installed on a resin substrate similarly as in the above-described embodiment, and the processing S2 to processing S5 were conducted. The bump pitch (inter-bump distance) of the bumps for coupling the semiconductor element with the resin substrate was 169 μm. A solder section and the above-described bumps of the resin substrate were composed of lead-free solder (more specifically, Sn₃Ag_{0.5}Cu). Thereafter, the substrate was left in a clean room at a temperature of 22.5 degree C. and a humidity of 50% for 480 minutes. The water content of the substrate of at this time was considered to be 0.055% according to FIGS. 3 and 4. Next, the semiconductor device was disposed in a heating apparatus (periphery of heating unit (hot plate) was opened to atmospheric air) at a temperature of 95 degree C., and then was taken out after 150 seconds. In such case, the water content of the resin substrate was 0.02% (FIG. 5). The resin (underfill) was supplied within 3 minutes after the substrate was taken out from the heating apparatus. Since the supply of the resin was started within 3 minutes, it is considered that the water content of the resin substrate was 0.02%. A thermosetting epoxy resin was employed for the resin. Thereafter(immediately after filling the resin (under the condition that the water content of the resin substrate was 0.02%)), the substrate was heated at 125 degree C. to 135 degree C. for 2 hours to cure the resin.

### Example 2

A semiconductor device having a resin substrate of water content of 0.055% was installed in the heating apparatus similarly as in Example 1, and was taken out after 330 seconds. In this time, the water content of the substrate was 0.017%. The resin was supplied within 3 minutes after the substrate was taken out from the heating apparatus. Since the supply of the resin was started within 3 minutes, it is considered that the water content of the resin substrate was 0.017%. Then, the resin was cured, similarly as in Example 1.

### Comparative Example 1

A resin was supplied into a semiconductor device having a resin substrate of the water content of 0.055% without installing the substrate in the heating apparatus, and then the resin was cured. The type of the resin and the curing condition were the same as employed in Example 1.

### Comparative Example 2

Similarly as in Example 1, a semiconductor device having a resin substrate of the water content of 0.055% was disposed in the heating apparatus, was taken out after 90 seconds. In this time, the water content of the substrate was 0.025%. The resin was supplied within 3 minutes after the substrate was taken out from the heating apparatus. Since the supply of the resin was started within 3 minutes, it is considered that the water content of the resin substrate was 0.025%. Then, the resin was cured, similarly as in Example 1.

### Result of Examples and Comparative Examples

Relation of the number of generated voids in the resin (underfill resin) respective semiconductor devices with the water content was measured. The number of the generated voids was counted by a scanning acoustic tomograph (SAT) and by an observation over a flat cross section. The voids having a diameter of 75 μm or larger were counted as the generated voids. The results are shown in FIG. 5.

It can be understood from FIG. 5 that no void was generated when the water content of the resin substrate was equal to or lower than 0.02%. On the contrary, it can also be understood that voids were generated in Comparative Examples. Since a number of voids were generated in Comparative Example 1, such result is not shown in FIG. 5. In addition, when the heat treatment processes as employed in the installation of the installation substrate were conducted for the respective semiconductor devices of the respective Comparative Examples, a protrusion of solder in the void was confirmed in each case, leading to a short-circuit. On the contrary, when the semiconductor devices of the respective Example were installed in the installation substrate, no short-circuit was caused due to an absence of void, and thus no influence in the quality of the semiconductor device was found.

It is apparent that the present invention is not limited to the above embodiment, and may be modified and changed without departing from the scope and spirit of the invention.

What is claimed is:

1. A process for manufacturing a semiconductor device, said device comprising a resin substrate and a semiconductor element installed on said resin substrate,
said process including:
electrically coupling said resin substrate with said semiconductor element through a plurality of electroconductive bumps over said resin substrate;
controlling a water content of said resin substrate to equal to or lower than 0.02% by heating said resin substrate and said semiconductor element while maintaining the coupling of said substrate with said element through said bumps; and
filling a space surrounded by said semiconductor element, said resin substrate and said bump with a resin, and curing the resin,
wherein said filling the space with the resin and curing the resin includes filling the space with said resin under the condition that the water content of said resin substrate is equal to or lower than 0.02%.

2. The process for manufacturing the semiconductor device as set forth in claim 1, said process further including:
determining time-variation in the water content of said resin substrate;
determining a relation of the water content of said resin substrate over a heating time at a heating temperature employed in said controlling the water content; and
degassing said resin substrate and said semiconductor element by heating said resin substrate and said semiconductor element to remove a gas derived from a constituent of said resin substrate, said degassing the resin substrate and the semiconductor element being carried out after said electrically coupling the resin substrate with the semiconductor element through said plurality of electroconductive bumps on said resin substrate and before said controlling the water content;
wherein time elapsed from the end of said degassing the resin substrate and the semiconductor element to the start of said controlling the water content is determined, and the water content of said resin substrate immediately before said controlling the water content is determined based on the time-variation of the water content of said resin substrate, and
wherein the heating time in said controlling the water content is defined, on the basis of said determined water content, and on the basis of the relation between the water content of said resin substrate at the heating temperature in said controlling the water content and the heating time, so that the water content of said resin substrate is provided as equal to or lower than 0.02% in said controlling the water content.

3. The process for manufacturing the semiconductor device as set forth in claim 2, further including
curing said resin by heating said semiconductor element, said resin substrate, said bump and said resin, after said filling the space surrounded by said semiconductor element, said resin substrate and said bump with the resin,
wherein the heating temperature in said degassing the resin substrate and the semiconductor element is higher than the heating temperature in said controlling the water content and than the heating temperature in said curing said resin.

4. The process for manufacturing the semiconductor device as set forth in claims 1, wherein solder section coupled to said bump is formed in the surface of said resin substrate, and said bump and said solder section are formed of lead-free solder.

5. The process for manufacturing the semiconductor device as set forth in claims 1, wherein a distance between adjacent pair of said bumps is equal to or smaller than 200 μm.

6. The process for manufacturing the semiconductor device as set forth in claims 1, wherein said resin substrate is a build-up substrate composed of alternately disposed insulating layers and conductor interconnect layers, and has an insulating film having an opening in the surface of the substrate, said insulating layers containing a resin.

7. A semiconductor device manufactured by the process for manufacturing the semiconductor device as set forth in claim 1.
